(19) United States
(12) Patent Application Publication
(10) Pub. No.: US 2012/0153380 A1
(43) Pub. Date: Jun. 21, 2012

(54) METHOD FOR FABRICATING SEMICONDUCTOR DEVICE

(76) Inventors: Sang-Do Lee, Gyeonggi-do (KR); Uk Kim, Gyeonggi-do (KR)

(21) Appl. No.: 13/150,644

(22) Filed: Jun. 1, 2011

(30) Foreign Application Priority Data
Dec. 17, 2010 (KR) 10-2010-0130185

(51) Int. Cl. H01L 29/78; H01L 21/28; H01L 21/306

(52) U.S. Cl. 257/330; 438/696; 438/589; 257/E21.215; 257/E21.209; 257/E29.262

(57) ABSTRACT

A method for fabricating a semiconductor device includes forming a first trench by etching a substrate, forming first spacers on sidewalls of the first trench, forming a second trench by etching the substrate under the first trench, forming second spacers on sidewalls of the second trench, forming a third trench, which has a wider width than a width between the second spacers, by etching the substrate under the second trench, forming a liner layer on the surface of the third trench, and exposing one of the sidewalls of the second trench by selectively removing the second spacers.

### CROSS-REFERENCE TO RELATED APPLICATIONS

The present application claims priority of Korean Patent Application No. 10-2010-0130185, filed on Dec. 17, 2010, which is incorporated herein by reference in its entirety.

### BACKGROUND

1. Field

Exemplary embodiments of the present invention relate to a method for fabricating a semiconductor device, and more particularly, to a method for fabricating a semiconductor device making a side contact between an active region and bit line.

2. Description of the Related Art

Patterns of semiconductor devices have shrunk down in size for yield improvement. Due to such a pattern shrinkage, a mask process has been performed in a smaller scale. Thus, while a sub-40 nm semiconductor device may use ArF photoresist (PR) mask, scaling limits are being reached in forming finer patterns.

In this regard, a different patterning technique has been developed for a memory device such as a DRAM, and a three-dimensional cell fabrication technique has been introduced accordingly.

A MOSFET element with a planar channel is reaching limits in terms of a leakage current, an on-current, and a short channel effect, which are caused by the pattern shrinkage of a memory device, and thus, it is difficult to further reduce the size of the memory device. Therefore, a semiconductor device using a vertical channel is being developed.

As for a semiconductor device with a vertical channel, a pillar-type active region extending vertically is formed on a substrate, and a surround-type gate electrode surrounding the active region, which is referred to as a vertical gate (VG), is formed on the substrate. Junction regions including a source region and a drain region are formed above and under the active region on the sides of the gate electrode. In this manner, the semiconductor device with the vertical channel is fabricated. A buried bit line (BBL) is connected to one of the junction regions.

In order to form the buried bit line, an ion implantation process is performed to implant dopants. However, as the semiconductor device shrinks down in size, the implantation of dopant alone is reaching limits in reducing the resistance of the buried bit line and thus cause the degradation of device characteristics.

In this regard, a technique which reduces a resistance by forming a buried bit line of a metal layer is proposed. In order to make a contact between an active region and a buried bit line, a side contact process of exposing one sidewall of an active region is performed.

Since the height of the buried bit line is relatively small, a side contact portion is formed in one sidewall of the active region in order for connection between the active region and the buried bit line.

However, as the integration density of the device is increased, the width of the active region is reduced and the depth of the active region is increased. Hence, it is difficult to perform a process of forming a side contact portion which partially exposes one sidewall of the active region. In addition, even though the side contact portion is formed, there is a limit to forming the side contact portion with uniform depth.

### SUMMARY

An embodiment of the present invention is directed to a method for fabricating a semiconductor device, which is capable of easily forming a side contact portion partially exposing one sidewall of an active region and forming the side contact portion with uniform depth.

In accordance with an embodiment of the present invention, a method for fabricating a semiconductor device includes: forming a first trench by etching a substrate; forming first spacers on sidewalls of the first trench; forming a second trench by etching the substrate under the first trench; forming second spacers on sidewalls of the second trench; forming a third trench, which has a wider width than a width between the second spacers, by etching the substrate under of the second trench; forming a liner layer on the surface of the third trench; and exposing one of the sidewalls of the second trench by selectively removing the second spacers.

In accordance with another embodiment of the present invention, a method for fabricating a semiconductor device includes: forming a first trench by etching a substrate; forming first spacers on sidewalls of the first trench; forming a second trench by etching the substrate under the first trench; forming second spacers on sidewalls of the second trench; forming a third trench, which has the same width as the second trench, by etching the substrate under the second trench; forming a liner layer on the surface of the third trench; exposing one of the sidewalls of the second trench by selectively removing the second spacers; forming a junction region in the substrate on the exposed sidewall of the second trench; and forming a buried bitline connected to the junction region and filling the second and third trenches.

In accordance with further embodiment of the present invention, a semiconductor device includes: a trench formed in a substrate; an active region defined in the substrate by the trench; a buried bit line filling the trench and connected with the active region through a portion of a first sidewall of the trench; and first to third spacers formed between the active region and the buried bit line at different depths from a surface of the substrate.

### BRIEF DESCRIPTION OF THE DRAWINGS

FIGS. 1A to 1K are cross-sectional views illustrating a method for fabricating a semiconductor device in accordance with an embodiment of the present invention.

FIG. 2 illustrates an embodiment of a computer system according to an aspect of the present invention,

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

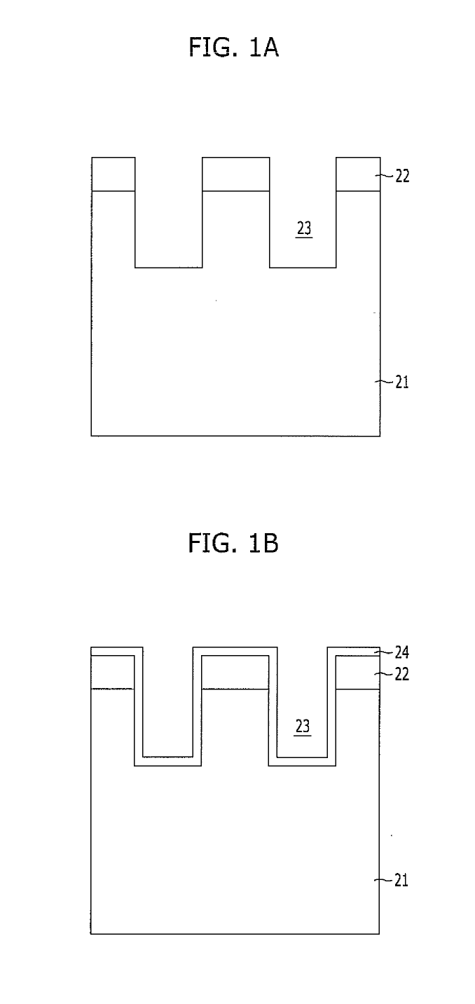

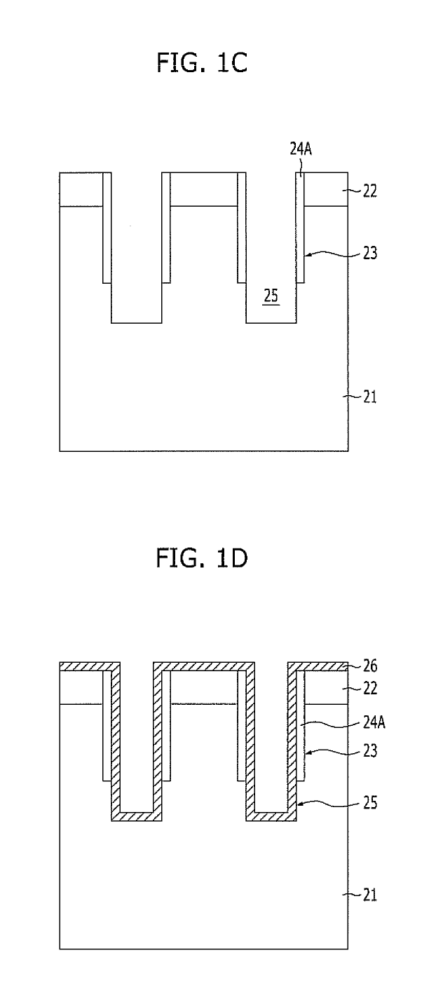

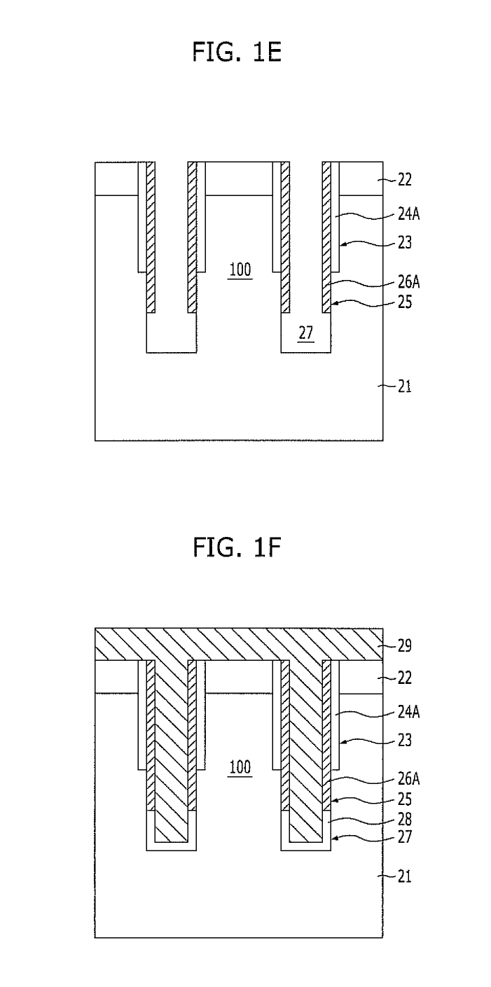

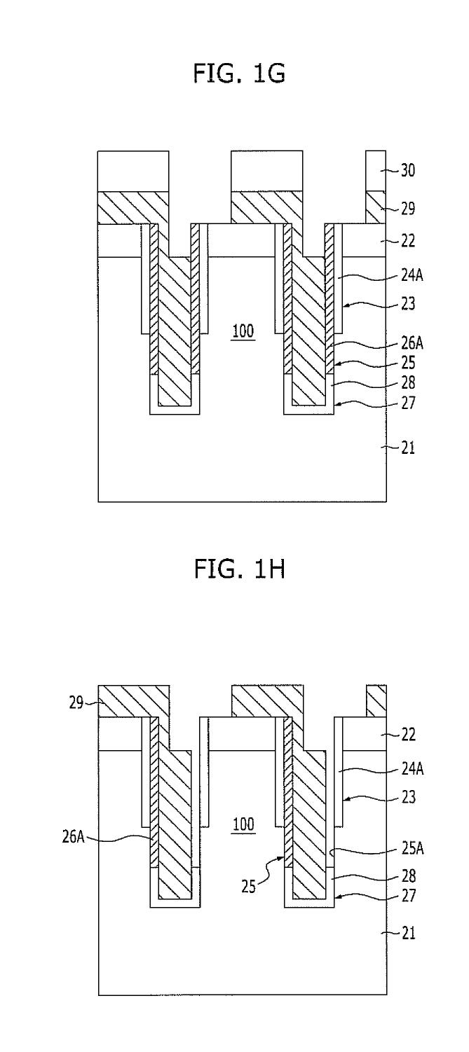

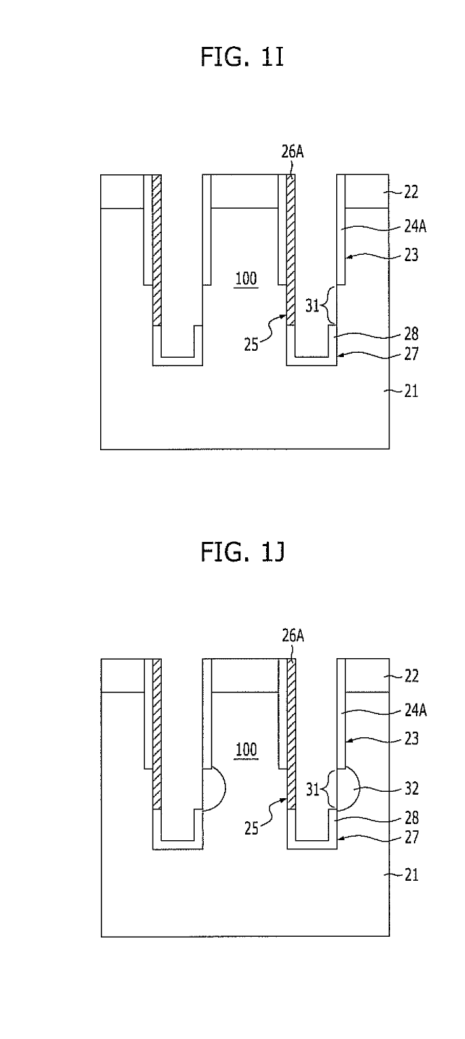

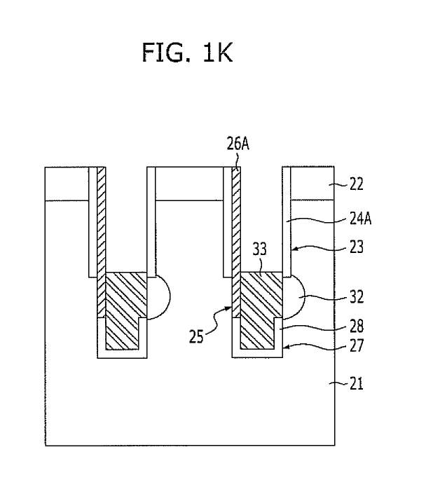

FIGS. 1A to 1K are cross-sectional views illustrating a method for fabricating a semiconductor device in accordance with an embodiment of the present invention.

Referring to FIG. 1A, a hard mask pattern 22 is formed on a semiconductor substrate 21. The semiconductor substrate 21 includes a silicon substrate. The hard mask pattern 22 may include an oxide layer or a nitride layer, or it may have a stacked structure in which a nitride layer and an oxide layer are stacked. For example, a hard mask (HM) nitride layer and a hard mask oxide layer may be sequentially stacked.

The hard mask pattern 22 is formed using a photoresist layer (not shown) which is patterned in a line-space type.

A primary trench etch process is performed using the hard mask pattern 22 as an etch barrier. That is, a first trench 23 is formed in the semiconductor substrate 21 by etching the semiconductor substrate 21 by a predetermined depth using the hard mask pattern 22 as an etch barrier. Since the first trench 23 also is formed by the hard mask pattern 22, the first trench 23 is patterned in a line-space type. Accordingly, the first trench 23 has a line type.

The primary trench etch process is performed by an anisotropic etch process. When the semiconductor substrate 21 is a silicon substrate, the anisotropic etch process may be performed by a plasma dry etch process which uses Cl₂ gas or HBr gas solely or uses the mixture of Cl₂ gas and HBr gas.

Referring to FIG. 1B, a first liner layer 24 is formed to cover the bottom and sidewall of the first trench 23. The first liner layer 24 may include an oxide layer such as a silicon oxide layer. The first liner layer 24 may be formed using a wall oxidation process.

Referring to FIG. 1C, a secondary trench etch process is performed to form a second trench 25. In the secondary trench etch process, the first liner layer 24 formed on the hard mask pattern 22 and on the bottom of the first trench 23 is etched, and then, the semiconductor substrate 21 under the first trench 23 is etched by a predetermined depth. At this time, the first liner layer 24 is etched to form first spacers 24A on sidewalls of the first trench 23 and the hard mask pattern 22. The first spacers 24A are formed by etching back the first liner layer 24. The sidewalls of second trench 25 are aligned with the sidewalls of the first spacers 24A. The sidewalls of the second trench 25 may have a smaller length than those of the first trench 23.

Referring to FIG. 1D, a second liner layer 26 is formed on a resulting structure including the second trench 25. The second liner layer 26 is formed on the entire surface of the semiconductor substrate 21, while covering the bottom and sidewall of the second trench 25. The second liner layer 26 includes a nitride layer such as a silicon nitride layer.

Referring to FIG. 1E, a tertiary trench etch process is performed to form a third trench 27. In the tertiary trench etch process, the second liner layer 26 formed on the hard mask pattern 22 and on the bottom of the second trench 25 is etched, and then, the semiconductor substrate 21 under the second trench 25 is etched by a predetermined depth. At this time, the second liner layer 26 is etched to form second spacers 26A. The second spacers 26A are formed by etching back the second liner layer 26. The second spacers 26A cover the sidewalls of the second trench 25 and also cover the sidewalls of the first spacer 24A.

In order to form the third trench 27, an isotropic etch process may be performed, or an anisotropic etch process and an isotropic etch process may be sequentially performed. Due to the isotropic etch process, the third trench 27 widen under the second spacer 26A is formed. That is, the width of the third trench 27 is expanded in a direction from inner sides to outer sides of the second spacers 26A. The width of the third trench 27 is larger than the width between the second spacers 26A. The width of the third trench 27 may be equal to the width of the second trench 25. The sidewalls of the third trench 27 have a smaller length than those of the first trench 24, and the length is equal to or larger than that of the second trench 25.

When the third trench 27 is formed as above, a plurality of bodies 100 separated by a triple trench including the first trench 23, the second trench 25, and the third trench 27 are formed in the semiconductor substrate 21. Due to the triple trench, the body 100 has a line-type pillar structure with both sidewalls which include one sidewall and the other sidewall. The body 100 is an active region in which a channel, a source, and a drain of a transistor are formed. Since the semiconductor substrate 21 includes a silicon substrate, the body 100 becomes a silicon body.

Referring to FIG. 1F, a third liner layer 28 is formed on the surface of the third trench 27. The third liner layer 28 includes an oxide layer such as a silicon oxide layer. Since the third liner layer 28 is formed using a wall oxidation process, the third liner layer 28 is formed on only the bottom and sidewall of the third trench 27. The thickness of the third liner layer 28 is adjusted to be equal to the thickness of the second spacer 26A.

A sacrificial layer 29 is formed on a resulting structure, including the third liner layer 28, to gap-fill the triple trench. The sacrificial layer 29 is to be removed in a subsequent process. For example, the sacrificial layer 29 may include undoped polysilicon. A planarization process using chemical mechanical polishing (CMP) may be subsequently performed.

Referring to FIG. 1G, a photoresist pattern 30 is formed using a photoresist layer. The photoresist pattern 30 is used as an etch barrier for partially etching the sacrificial layer 29 in a subsequent process. The photoresist pattern 30 has one side on the surface of the sacrificial layer 29 formed on the hard mask pattern 22 and the other side on the surface of the sacrificial layer 29 formed on the triple trench. That is, the photoresist pattern 30 is patterned to expose a portion of the region between the triple trenches. The photoresist pattern 30 is called an “OSC mask”.

The sacrificial layer 29 is partially etched using the photoresist pattern 30 as an etch barrier. The “partial etch” refers to a process of etching only a portion of the sacrificial layer 29 to expose a upper portion of the sidewall of the second spacer 26A.

When the sacrificial layer 29 is partially etched, the second spacer 26A formed on one of both sidewalls of the body 100 is exposed. The process of partially etching the sacrificial layer 29 is performed using a dry etch process. Since the sacrificial layer 29 is an undoped polysilicon layer, HBr- or Cl₂-based compounds are used, and a vertical profile is obtained by additionally adding O₂, N₂, He, or Ar. The exposed second spacer 26A is a formed on one of both sidewalls of the body 100. For example, in the drawings, the second spacer 26A formed on the left sidewall of the body 100 is exposed, and the second spacer 26A formed on the right sidewall of the body is not exposed.

In addition, a strip process and a wet etch process may be performed in order to remove residues remaining after the dry etch process. The strip process applies plasma using microwave, and uses a mixed gas of N₂/O₂/H₂. The wet etch process may use NH₄OH, H₂SO₄, and H₂O₂.

Referring to FIG. 1H, after the photoresist pattern 30 is removed, the exposed second spacer 26A is removed. Since the second spacer 26A includes a nitride layer, a wet etch process is used. For example, when a nitride strip process using a wet etch is applied, a mixture of H₃PO₄ and H₂O is used.

When the exposed second spacer 26A is removed, only the second spacer 26A formed on one of both sidewalls of the body 100 remains. Through the space where the second spacer 26A is removed, the first spacers 24A formed on one of both sidewalls of the body 100 are exposed. For example, in the drawings, the first spacer 24A formed on the left sidewall of the body 100 is exposed, and the first spacer 24A formed on the right sidewall of the body 100 is not exposed.

As such, when the second spacer 26A is selectively removed, a portion of one sidewall of the body 100 is exposed. That is, one sidewall of the second trench 25 is exposed.

Referring to FIG. 1I, the sacrificial layer 29 is removed. A wet etch process or a dry etch process is used to remove the sacrificial layer 29. In the case of using the dry etch process, HBr- or Cl₂-based compounds are used, and a vertical profile is obtained by additionally adding O₂, N₂, He, or Ar. In the case of using the wet etch process, a cleaning solution (for example, NH₄OH/H₂SO₄ or NH₄OH/H₂O₂) which has a high selectivity to a nitride layer and an oxide layer is used. When the sacrificial layer 29 is removed, the first spacer 24A and the second spacer 26A remain without being removed.

As described above, when the sacrificial layer 29 is removed, a side contact portion 31 is formed to expose a portion of one sidewall of the body 100. That is, one sidewall of the second trench 25 is exposed and thus the side contact portion 31 exposing a portion of one sidewall of the body 100 is formed.

The side contact portion 31 partially exposes one sidewall of the body 100 which is separated by the triple trench including the first to third trenches 23, 25, and 27.

Insulation layers are coated on the surface of the body 100 except for the side contact portion 31. In other words, the first spacers 24A are coated on both sidewalls of the first trench 23, and the remaining second spacer 26A is formed on one sidewall of the first trench 23. The third liner layer 28 is coated on the surface of the third trench 27. One sidewall of the second trench 25, in which the side contact portion 31 is formed, is exposed, and the other sidewall thereof is coated with the second spacer 26A.

As such, the side contact portion 31 is formed to expose a discontinuous point of the insulation layer including the first spacer 24, the second spacer 26A, and the third liner layer 28, that is, one sidewall of the second trench 27. The side contact portion 31 exposing only one sidewall of the body 100 may be simply referred to as one side contact (OSC).

According to the above description, the side contact portion 31 is formed in a portion of one sidewall of the body 100. In a subsequent process, a junction region is formed in the portion of one sidewall of the body 100. The side contact portion 31 is a region in which the junction region and a buried bit line are in contact with each other. In addition a contact plug may be connected to one sidewall of the body 100 exposed by the side contact portion 31.

In the exemplary embodiment of the present invention, since the triple trench process is used, the side contact portion 31 partially exposing one sidewall of the body 100 can be formed through a simple process. In addition, since the triple trench process is used, the depth of the side contact portion 31 can be easily adjusted. Hence, the depth of the subsequent junction region can be adjusted.

Referring to FIG. 1J, a junction region 32 is formed in one sidewall of the body 100 exposed by the side contact portion 31. The junction region 32 may be formed using an ion implantation process or a plasma doping process. In addition, the junction region 32 may be formed by gap-filling a doped layer, such as doped polysilicon, and performing a thermal treatment thereon. A dopant doped into the doped layer may include N-type impurities such as phosphorus (P). Therefore, the junction region 32 becomes an N-type junction.

Referring to FIG. 1K, a buried bit line 33 connected to the junction region 32 is formed. The buried bit line 33 is arranged in parallel to the body 100. The buried bit line 33 is so high as to fill the second trench 25 at least. Except for the portion connected to the junction region 32, the buried bit line 33 is insulated from the semiconductor substrate 21B by the first spacer 24A, the second spacer 26A, and the third liner layer 28. The buried bit line 33 includes a titanium (Ti) layer, a titanium nitride (TiN) layer, and a tungsten (W) layer. For example, the buried bit line 33 is formed by forming a titanium layer and a titanium nitride layer thinly and gap-filling a tungsten layer. A planarization process and an etch-back process are performed so that the buried bit line 33 is so high as to fill the second trench 25 at least. The titanium layer and the titanium nitride layer are a barrier metal. If necessary, after the barrier metal is formed, a silicide layer may be formed on the surface of the junction region 32. The silicide layer makes an ohmic contact between the junction region 32 and the buried bit line 33 and reduces a contact resistance.

As such, since the buried bit line 33 is formed of a metal layer, a resistance thereof is low. In addition, since only one buried bit line 33 is in contact with one junction region 32, a semiconductor device may be formed in high integration.

In accordance with the exemplary embodiments of the present invention, since the triple trench process is used, the depth and size of the side contact portion can be uniformly adjusted. In addition, the process time and cost for forming the side contact portion can be reduced.

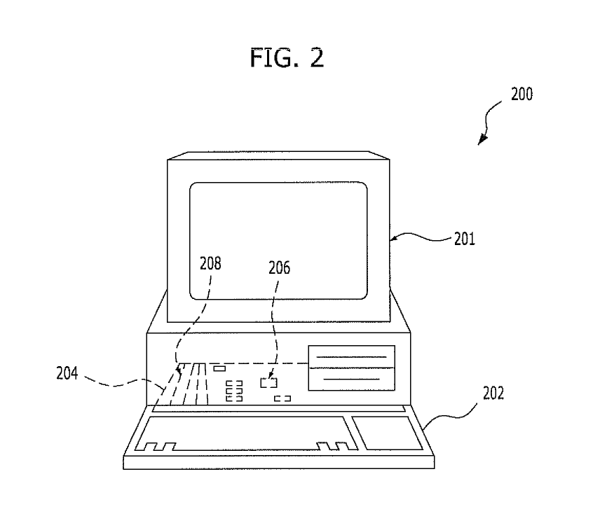

FIG. 2 illustrates an embodiment of a computer system according to an aspect of the present invention.

Referring to FIG. 2, a computer system 200 includes an output device (e.g., monitor) 201, an input device (e.g., keyboard) 202 and a motherboard 204.

The motherboard 204 may carry a data processing unit (e.g., microprocessor) 206 and at least one memory device 208. The memory device 208 may comprise various aspects of the invention described above. The memory device 208 may comprise an array of memory cells. Various components of the computer system 200 including the processor 206 may comprise at least one memory construction described in the present invention.

The processor device 206 may correspond to a processor module, and associated memory utilized with the module may comprise teachings of the present invention.

The memory device 208 may correspond to a memory module. For example, single in-line memory modules (SIMMs) and dual in-line memory modules (DIMMs) may be used in the implementations which utilize the teachings of the present invention.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a first trench by etching a substrate;
forming first spacers on sidewalls of the first trench;
forming a second trench by etching the substrate under the first trench;
forming second spacers on sidewalls of the second trench;
forming a third trench, which has a wider width than a width between the second spacers, by etching the substrate under the second trench;
forming a liner layer on the surface of the third trench; and
exposing one of the sidewalls of the second trench by selectively removing the second spacers.

2. The method of claim 1, wherein the third trench is formed by an isotropic etch process.

3. The method of claim 1, wherein the third trench is formed by sequentially performing an anisotropic etch process and an isotropic etch process.

4. The method of claim 1, wherein the third trench is formed to have the same width as the second trench.

5. The method of claim 1, wherein the liner layer is formed by a wall oxidation process.

6. The method of claim 1, wherein the exposing one of the sidewalls of the second trench comprises:
forming a sacrificial layer gap-filling the first to third trenches over a resulting structure in which the liner layer is formed;
forming a photoresist pattern over the sacrificial layer;
selectively exposing the second spacers by etching the sacrificial layer using the photoresist pattern as an etch barrier;
removing the exposed second spacer; and
removing the sacrificial layer.

7. The method of claim 6, wherein the sacrificial layer comprises an undoped polysilicon layer.

8. The method of claim 1, wherein the first spacers and the liner layer are formed using an oxide layer, and the second spacers are formed using a nitride layer.

9. A method for fabricating a semiconductor device, comprising:
forming a first trench by etching a substrate;
forming first spacers on sidewalls of the first trench;
forming a second trench by etching the substrate under the first trench;
forming second spacers on sidewalls of the second trench;
forming a third trench, which has the same width as the second trench, by etching the substrate under the second trench;
forming a liner layer on the surface of the third trench;
exposing one of the sidewalls of the second trench by selectively removing the second spacers;
forming a junction region in the substrate on the exposed sidewall of the second trench; and
forming a buried bit line connected to the junction region and filling the second and third trenches.

10. The method of claim 9, wherein the third trench is formed by an isotropic etch process.

11. The method of claim 9, wherein the third trench is formed by sequentially performing an anisotropic etch process and an isotropic etch process.

12. The method of claim 9, wherein the liner layer is formed by a wall oxidation process.

13. The method of claim 9, wherein the exposing one of the sidewalls of the second trench comprises:
forming a sacrificial layer gap-filling the first to third trenches over a resulting structure in which the liner layer is formed;
forming a photoresist pattern over the sacrificial layer;
selectively exposing the second spacers by etching the sacrificial layer using the photoresist pattern as an etch barrier;
removing the exposed second spacer; and
removing the sacrificial layer.

14. The method of claim 13, wherein the sacrificial layer comprises an undoped polysilicon layer.

15. The method of claim 9, wherein the first spacers and the liner layer are formed using an oxide layer, and the second spacers are formed using a nitride layer.

16. A semiconductor device, comprising:
a trench formed in a substrate;
an active region defined in the substrate by the trench;
a buried bit line filling the trench and connected with the active region through a portion of a first sidewall of the trench; and
first to third spacers formed between the active region and the buried bit line at different depths from a surface of the substrate.

17. The semiconductor device of claim 16, wherein one of the first to third spacers is formed on a second sidewall of the trench other than the first sidewall while the others of the first to third spacers are formed on the first and second sidewalls of the trench.
